(19) United States
(12) Patent Application Publication
(10) Pub. No.: US 2025/0048552 A1
(43) Pub. Date: Feb. 6, 2025

(54) CIRCUIT BOARD AND IMAGE FORMING APPARATUS

(71) Applicant: CANON KABUSHIKI KAISHA, Tokyo (JP)

(72) Inventor: SHUICHI NAKAMURA, Chiba (JP)

(21) Appl. No.: 18/790,285

(22) Filed: Jul. 31, 2024

(30) Foreign Application Priority Data
Aug. 3, 2023 (JP) 2023-126986

(51) Int. Cl. H05K 1/11; H05K 1/02; H05K 1/18

(52) U.S. Cl. CPC H05K 1/116; H05K 1/0206; H05K 1/0209; H05K 1/114; H05K 1/181; H05K 2201/066; H05K 2201/10689

(57) ABSTRACT

A circuit board includes a first surface having a first mounting region configured so that a first electronic part is mounted or mountable to the first mounting region, and a second surface having a second mounting region configured so that a second electronic part is mounted or mountable to the second mounting region, the second surface being different from the first surface, and a plurality of through vias penetrating through the circuit board, including at least a first through via and a second through via, wherein the circuit board includes an overlapping region in which the first mounting region and the second mounting region overlap each other as viewed from a direction perpendicular to the first surface, and wherein the first through via is arranged in the overlapping region.

### BACKGROUND OF THE INVENTION

### Field of the Invention

The present disclosure relates to a circuit board on which an electronic part is to be mounted, and to an image forming apparatus on which such a circuit board is mounted.

### Description of the Related Art

An integrated circuit (hereinafter referred to as “IC”) tends to have a larger amount of generated heat along with achievement of a higher density and a higher integration. Accordingly, a surface mount-type IC package adapted to reflow mounting to the circuit board includes a heat dissipation plate (thermal pad) provided for the purpose of dissipating heat of the IC. Heat generated in the IC is conducted to a heat transfer pattern (thermal land) on the circuit board provided to be opposed to the heat dissipation plate. In the heat transfer pattern, a through via (thermal via) for heat dissipation is formed. The heat conducted from the heat dissipation plate is dissipated to another layer of the circuit board via this through via. In U.S. Pat. No. 7,606,038, there is disclosed a circuit board in which a plurality of such through vias are formed. This circuit board is configured such that a resist opening portion is formed in a back surface thereof so that solder melting and flowing into the through via at the time of reflow mounting is absorbed by this resist opening portion.

### SUMMARY OF THE INVENTION

A circuit board according to one embodiment of the present disclosure includes a first surface having a first mounting region configured so that a first electronic part is mounted or mountable to the first mounting region, and a second surface having a second mounting region configured so that a second electronic part is mounted or mountable to the second mounting region, the second surface being different from the first surface, and a plurality of through vias penetrating through the circuit board, including at least a first through via and a second through via, wherein the circuit board includes an overlapping region in which the first mounting region and the second mounting region overlap each other as viewed from a direction perpendicular to the first surface, and wherein the first through via is arranged in the overlapping region, and the second through via has an opening area different from an opening area of the first through via.

An image forming apparatus according to another embodiment of the present disclosure includes a circuit board including a first surface having a first mounting region configured so that a first electronic part is mounted or mountable to the first mounting region, and a second surface having a second mounting region configured so that a second electronic part is mounted or mountable to the second mounting region, the second surface being different from the first surface, and a plurality of through vias penetrating through the circuit board, including at least a first through via and a second through via, wherein the circuit board includes an overlapping region in which the first mounting region and the second mounting region overlap each other as viewed from a direction perpendicular to the first surface, and wherein the first through via is arranged in the overlapping region, and the second through via has an opening area different from an opening area of the first through via, and a constituent part to be controlled by either one of the first electronic part or the second electronic part to form an image.

Further features of the present invention will become apparent from the following description of exemplary embodiments (with reference to the attached drawings).

### BRIEF DESCRIPTION OF THE DRAWINGS

FIG. 1 is an exemplary view of a configuration of a circuit board.

FIG. 2 is an exemplary view of a wiring pattern on a first surface side of the circuit board.

FIG. 3 is an exemplary view of a wiring pattern on a second surface side of the circuit board.

FIG. 4 is an exemplary view of a configuration of the circuit board.

FIG. 5 is an exemplary graph of a reflow temperature profile.

FIG. 6 is an explanatory view of a process in which a solder paste flows into a thermal via.

FIG. 7 is an explanatory view of the process in which the solder paste flows into the thermal via.

FIG. 8 is an explanatory view of the process in which the solder paste flows into the thermal via.

FIG. 9 is an exemplary view of a wiring pattern on the second surface side.

FIG. 10 is an exemplary view of a wiring pattern on the second surface side.

FIG. 11 is an exemplary view of a wiring pattern on the second surface side.

### DESCRIPTION OF THE EMBODIMENTS

Now, a description is given of exemplary embodiments of the present disclosure with reference to the accompanying drawings.

A circuit board of each of the embodiments is a printed wiring board on which a plurality of electronic parts are mounted and the electronic parts are connected to each other by printed wiring. This circuit board is manufactured by mounting a large number of electronic parts thereon. Each of the electronic parts includes a heat dissipation plate, and is configured to dissipate heat to the circuit board. Now, an IC package including a heat dissipation plate and a built-in IC is described as an example of the electronic part. The circuit board includes a thermal via that is a through via for heat dissipation, and diffuses heat of the electronic part to the inside via the thermal via.

There is a possibility that it becomes difficult to procure the electronic part to be mounted on the circuit board for various reasons such as distribution, environment, and accidents. For example, shortage of supply of ICs has recently been a problem. In order to avoid such a situation, it is required to make a research in advance of a replaceable electronic part (replacement product) having the same function and the same or similar shape and specification for each of the electronic parts. In a case where a problem occurs in part procurement of a genuine product, the replacement product may be procured so that the manufacture of the circuit board can be continued.

On the circuit board, IC packages are exclusively mounted on a first surface (upper surface) and a second surface (lower surface) different from the first surface. In a mounting region for the IC package (hereinafter referred to as “first IC package”) on the first surface, a heat transfer pattern for conducting heat from the heat dissipation plate is formed. In a mounting region for the IC package (hereinafter referred to as “second IC package”) on the second surface, a heat transfer pattern for conducting heat from the heat dissipation plate is formed. For example, the first IC package is a genuine product, and the second IC package is a replacement product.

In the embodiments, a description is given of a case in which the size of the first IC package is larger than the size of the second IC package. Accordingly, an area of the mounting region (heat transfer pattern) for the first IC package to be provided on the first surface is larger than an area of the mounting region (heat transfer pattern) for the second IC package to be provided on the second surface. In a case where the circuit board is viewed from a first surface direction (direction perpendicular to the first surface), the mounting region (heat transfer pattern) for the second IC package is included in the mounting region (heat transfer pattern) for the first IC package. Thermal vias are formed in the heat transfer pattern. A part of the plurality of thermal vias is formed in a region (overlapping region) in which the mounting region (heat transfer pattern) for the first IC package and the mounting region (heat transfer pattern) for the second IC package overlap each other as viewed from the first surface direction (direction perpendicular to the first surface). In this manner, the board area is reduced, and a part of the thermal vias is shared by the first IC package and the second IC package.

### First Embodiment

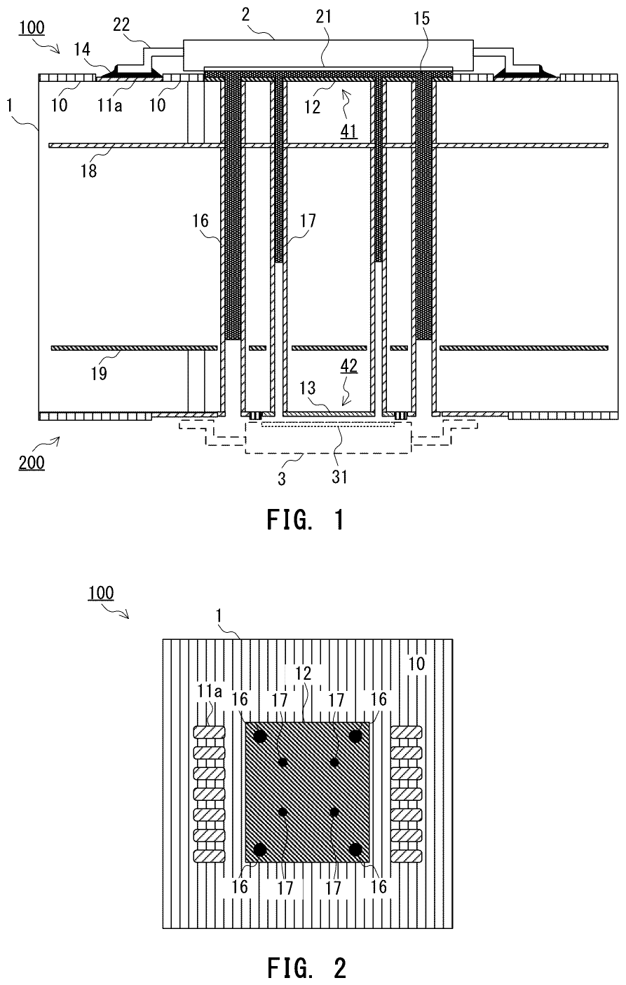

FIG. 1 is an exemplary view of a configuration of a circuit board of a first embodiment of the present disclosure. In FIG. 1, a first surface 100 of the circuit board 1 is on the upper side. A first IC package 2 on the first surface 100 and a second IC package 3 on a second surface 200 are exclusively mounted on the circuit board 1. FIG. 1 shows a state in which the first IC package 2 is mounted, and the second IC package 3 is indicated by dotted lines. The first IC package 2 includes a heat dissipation plate 21, and the second IC package 3 includes a heat dissipation plate 31.

The first IC package 2 and the second IC package 3 include built-in ICs having the same function. For example, the first IC package 2 and the second IC package 3 include built-in ICs having a large heat generation amount, such as DC-DC converters or motor drivers. Accordingly, the first IC package 2 and the second IC package 3 are packages including the heat dissipation plates 21 and 31 and having high heat dissipation performance.

In the first embodiment, from the viewpoint of part procurement, the first IC package 2 and the second IC package 3 have different sizes. A description is given here of a case in which the first IC package 2 has a larger size. The size of the heat dissipation plate corresponds to the size of the IC package. Accordingly, in this case, the heat dissipation plate 21 has a size larger than that of the heat dissipation plate 31. For example, the first IC package 2 is a package of thin-shrink small outline package (TSSOP)-14. The second IC package 3 is a package of small outline package (SOP)-8. The packages of the IC packages may be IC packages of other types as long as the IC packages include heat dissipation plates.

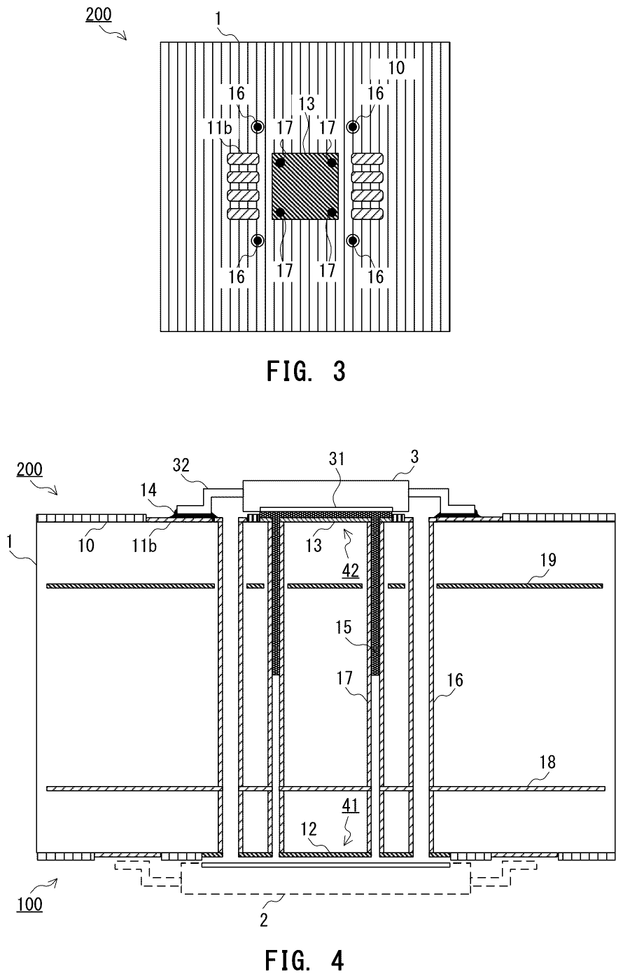

The circuit board 1 is a circuit board having a multilayer structure. In the first embodiment, the circuit board 1 has a four-layer configuration made of a general flame retardant (FR material) having a thickness of 1.6 mm, however, the number of layers is not limited to four, but can be any other number. FIG. 2 is an exemplary view of a wiring pattern on the first surface side of the circuit board 1 on which the first IC package 2 is to be mounted. FIG. 3 is an exemplary view of a wiring pattern on the second surface side of the circuit board 1 on which the second IC package 3 is to be mounted. FIG. 4 is an exemplary view of a configuration of the circuit board 1, in which the second surface side is the upper side.

On each of the first surface 100 and the second surface 200, a solder resist 10 is applied. On the solder resist 10 of the first surface 100, a land 11a for lead connection and a heat transfer pattern 12 are provided. A lead electrode 22 of the first IC package 2 can be connected to the land 11a for lead connection, and the heat dissipation plate 21 of the first IC package 2 can be caused to adhere to the heat transfer pattern 12. A region in which the land 11a for lead connection and the heat transfer pattern 12 are formed corresponds to a mounting region 41 for the first IC package 2. On the solder resist 10 of the second surface 200, a land 11b for lead connection and a heat transfer pattern 13 are provided. A lead electrode 32 of the second IC package 3 can be connected to the land 11b for lead connection, and the heat dissipation plate 31 of the second IC package 3 can be caused to adhere to the heat transfer pattern 13. A region in which the land 11b for lead connection and the heat transfer pattern 13 are formed corresponds to a mounting region 42 for the second IC package 3.

The land 11a for lead connection is connected (soldered) to the lead electrode 22 of the first IC package 2 with solder 14 in a case where a solder paste melts at the time of reflow. The land 11b for lead connection is similarly connected (soldered) to the lead electrode 32 of the second IC package 3 with the solder 14 in a case where the solder paste melts at the time of reflow.

The heat transfer pattern 12 and the heat transfer pattern 13 each have a rectangular shape, and are formed to have sizes corresponding to the sizes of the first IC package 2 and the second IC package 3 to be mounted thereon. In the first embodiment, the first IC package 2 has a size larger than that of the second IC package 3, and hence the heat transfer pattern 12 has a size larger than that of the heat transfer pattern 13. For the first IC package 2 and the second IC package 3, the mounting region 41 and the mounting region 42 are provided at positions opposed to each other across the circuit board 1. Accordingly, as viewed from the first surface side (direction perpendicular to the first surface), the region of the heat transfer pattern 13 is included in the region of the heat transfer pattern 12.

In the heat transfer pattern 12, a plurality of thermal vias 16 and 17 are formed. In the heat transfer pattern 13, a plurality of thermal vias 17 are formed. The plurality of thermal vias 17 are formed at four corners of the rectangular shape of the heat transfer pattern 13. The plurality of thermal vias 16 are formed at four corners of the rectangular shape of the heat transfer pattern 12. That is, the plurality of thermal vias 17 are formed in an overlapping region in which the heat transfer pattern 12 and the heat transfer pattern 13 overlap each other as viewed from the first surface side (direction perpendicular to the first surface), and are shared for heat dissipation of the first IC package 2 and the second IC package 3. The thermal vias 16 are formed in a region in which the heat transfer pattern 13 and the heat transfer pattern 12 do not overlap each other as viewed from the first surface side (direction perpendicular to the first surface), and are used for heat dissipation of the first IC package 2. In such a configuration, the thermal vias 17 pass through the heat transfer pattern 12 and the heat transfer pattern 13. The thermal vias 16 pass through the heat transfer pattern 12 and the second surface 200 outside of the heat transfer pattern 13.

In a case where the plurality of thermal vias 16 and 17 are thus formed, as described above, a large amount of solder may flow into the thermal vias 16 and 17 due to heating processing at the time when the IC package is mounted, depending on the arrangements of the thermal vias 16 and 17. In this case, even in a case where a resist opening portion is formed in the back surface as disclosed in U.S. Pat. No. 7,606,038, there is a possibility that it becomes difficult to reduce the inflow of the solder into the thermal vias 16 and 17. Such inflow of the solder into the thermal vias 16 and 17 leads to reduction of an amount of solder used for mounting the IC package. The reduction of the amount of solder may cause separation of the IC package from the circuit board 1. This separation causes reduction of the manufacturing yield of the circuit board 1. Accordingly, in the first embodiment, the following configuration is proposed.

In a case where the solder paste applied to the heat transfer pattern 12 melts at the time of reflow, molten solder 15 flows into the plurality of thermal vias 16 and 17 (see FIG. 1). At this time, a gap (stand-off) between the first IC package 2 (heat dissipation plate 21) and the heat transfer pattern 12 is determined based on the package standard. In the first embodiment, for example, the gap between the first IC package 2 (heat dissipation plate 21) and the heat transfer pattern 12 is 0 mm at minimum and 0.150 mm at maximum. Similarly, the gap between the second IC package 3 (heat dissipation plate 31) and the heat transfer pattern 13 is 0 mm at minimum and 0.152 mm at maximum.

The thermal via 16 and the thermal via 17 have different sizes. That is, the thermal via 16 and the thermal via 17 have different opening areas. In the first embodiment, the thermal via 17 is formed to have a size smaller than the size (opening area) of the thermal via 16. For example, the thermal via 16 is a through via having a diameter of 0.3 mm, and the thermal via 17 is a through via having a diameter of 0.25 mm. The thermal via 16 and the thermal via 17 are each plated on its inner side at a thickness of 15 μm. That is, in a case where the heat transfer pattern 12 is viewed from the first surface side (direction perpendicular to the first surface), the thermal vias 16 having a relatively large diameter are formed in a region not overlapping the heat transfer pattern 13, and the thermal vias 17 having a relatively small diameter are formed in the overlapping region overlapping the heat transfer pattern 13.

As illustrated in FIG. 1 and FIG. 4, the second layer of the circuit board 1 is a ground layer, and has copper foil 18 provided for supplying a ground voltage. The third layer is the power supply layer, and has a power supply pattern 19 provided for supplying a power supply voltage. Heat conducted through the thermal vias 16 and 17 is dissipated to other layers (second layer and third layer).

In general double-sided reflow mounting to the circuit board 1, small electronic parts, such as chip resistors and chip capacitors, are mounted in the first reflow step. In the second reflow step, large electronic parts, such as IC packages and electrolytic capacitors having a high height, are mounted. This operation is performed in order to prevent the electronic parts mounted in the first reflow step from falling by their own weights in a case where the solder melts by heating performed in the second reflow step. A surface on which the electronic parts are mounted in the first reflow step is referred to as “primary surface,” and a surface on which the electronic parts are mounted in the second reflow step is referred to as “secondary surface.”

Now, a method of mounting an IC package onto the primary surface and the secondary surface is described in detail. In the first embodiment, the first IC package 2 has a size larger than that of the second IC package 3, and hence the first IC package 2 has a larger weight. Accordingly, in the first reflow step, reflow is performed with the second surface 200 being used as the primary surface, and, in the second reflow step, reflow is performed with the first surface 100 being used as the secondary surface.

### <When First IC Package 2 is Mounted on Secondary Surface, and Second IC Package 3 is Yet to be Mounted>

As described above, the first IC package 2 is mounted on the secondary surface (first surface 100) in the second reflow step.

FIG. 5 is an exemplary graph of a general reflow temperature profile used in the reflow step. The horizontal axis represents a heating time of the reflow step, and the vertical axis represents a temperature corresponding to the heating time. A period in which the temperature is from 150° C. to 180° C. is a pre-heat period, and a period in which the temperature is 180° C. or more is a main heating period. In general, in a reflow furnace, the circuit board 1 has a temperature difference between the front surface and the inner layer thereof. For example, even in a case where the front surface of the circuit board 1 reaches 240° C. during the main heating period, the inner layer (inner side) may be 220° C.

This difference is caused because, even in a case where hot air is blown from an upper heater and a lower heater of the reflow furnace, the heat is absorbed by the inner layer of the circuit board 1 and thus the temperature is less liable to increase. In such a situation, the temperature inside of the thermal via varies between the front surface side and the inner layer side of the circuit board 1. Even when the molten solder flowing into the thermal via is 240° C. on the front surface side, in a case in which a GND pattern on the inner layer side is 220° C., the inner layer side draws away the heat.

The first IC package 2 is mounted in the second reflow step. Accordingly, even in a case where the solder protrudes to the primary surface side from the thermal vias 16 and the thermal vias 17, the protruding solder does not cause a problem because the mounting of the primary surface side is ended. However, the thermal vias 17 are arranged on the inner side of the heat transfer pattern 13 with respect to the thermal vias 16, and hence the solder is liable to protrude at the time of reflow mounting.

In the first embodiment, the thermal vias 17 each having a diameter smaller than that of each of the thermal vias 16 are arranged on the inner side of the heat transfer pattern 12 so that the protrusion of the solder from the thermal vias 17 is suppressed at the time of reflow mounting. Specifically, as described above, the diameter of the thermal via 16 is 0.3 mm, which is a normal diameter, and the diameter of the thermal via 17 is 0.25 mm, which is a small diameter. The thermal vias 17 are formed on the inner side of the heat transfer pattern 13.

In general, the diameter of the thermal via is about 0.3 mm. However, even in a case of a thermal via having a diameter of 0.3 mm, in a case where the thermal via is formed inside of the heat transfer pattern such as at a center portion of the heat transfer pattern, large solder protrusion is caused at a lower portion of the thermal via, depending on the reflow profile. It is inferred that this protrusion is caused because, at the center portion of the heat transfer pattern, a solder paste is present in an amount equal to or larger than a capacity filling the inside of the thermal via, and even the thermal via having the diameter of 0.3 mm sucks up the molten solder through the capillary phenomenon. Further, in a case of a thermal via having a diameter of 0.25 mm, even in a case where the thermal via is formed inside of the heat transfer pattern, solder protrusion did not occur at the time of reflow.

It is inferred that the inflow/protrusion of the solder does not occur in a case where the diameter of the thermal via is smaller than normal for the following three reasons.

1. The suck-up force of solder obtained by the capillary phenomenon (surface tension) becomes smaller as the diameter of the thermal via becomes smaller.

2. The pipe resistance of the molten solder serving as a viscous fluid becomes larger as the diameter of the thermal via becomes smaller.

3. The quantity of heat held by the molten solder flowing into the thermal via becomes smaller and the temperature is thus more likely to decrease as the diameter of the thermal via becomes smaller. In this case, when the temperature decreases, there is added a secondary effect that the surface tension further decreases and the viscosity increases to further increase the pipe resistance.

It is considered that, because of the three reasons described above, although solder protrusion occurs in the thermal via having the diameter of 0.3 mm, solder protrusion is reduced in the thermal via having the diameter of 0.25 mm. The mechanical basis of each of the three reasons described above is described below.

1. The capillary phenomenon (surface tension) becomes smaller as the diameter of the thermal via becomes smaller.

When a diameter, a contact angle, and surface tension are represented by “d”, “θ”, and S, respectively, a vertical-direction component F of the surface tension caused by the capillary phenomenon is expressed by (Equation 1) below.

$$F = π dS cos θ \qquad ( Equation l )$$

The vertical-direction component F of the surface tension acts as a force of accelerating the molten solder having a mass “m” flowing inside of the thermal via. It is understood from (Equation 1) that the vertical-direction component F of the surface tension is in proportion to the diameter “d” of the thermal via. Accordingly, in a case where the diameter of the thermal via is small, the solder suck-up force is decreased.

2. The pipe resistance of the molten solder serving as the viscous fluid becomes larger as the diameter of the thermal via becomes smaller.

In a case where the molten solder flowing into the thermal via is regarded as a viscous fluid (viscous liquid), a pipe resistance is caused with the thermal via being regarded as a pipe. The pipe resistance acts as a force of decelerating the molten solder flowing inside of the thermal via. The viscosity and the specific gravity of the molten solder are represented by “μ” and “ρ”, respectively, the thermal via is regarded as a pipe having a diameter of “d” and a length of L, and the molten solder is regarded as a Newtonian fluid. In this case, a pipe resistance P at the time of a pipe friction coefficient “λ”, a molten solder density “ρ”, and a flow velocity “v” inside the pipe is expressed by (Equation 2) below.

$$P = λ \cdot ( L / d ) \cdot ( {pv}^{2} ) \qquad ( Equation 2 )$$

In this case, a relationship between the pipe friction coefficient “λ” and a Reynolds number Re is expressed by (Equation 3) below.

$$λ = 64 / Re \qquad ( Equation 3 )$$

A relationship among the Reynolds number Re, a dynamic viscosity “v”, the viscosity “μ”, the density “ρ”, and the diameter “d” of the thermal via is expressed by (Equation 4) below.

$$Re = ( v \cdot d \cdot ρ ) / ( {μ}^{\times } 1 {0}^{- 3} ) \qquad ( Equation 4 )$$

From (Equation 2) to (Equation 4) above, the pipe resistance P is expressed by (Equation 5) below.

$$P = ( 64 / ( v \cdot d \cdot ρ ) / ( {μ}^{\times } 1 {0}^{- 3} ) ) \cdot ( L / d ) \cdot ( {pv}^{2} / 2 ) = ( 32 \cdot {μ}^{\times } 1 {0}^{- 3} \cdot L \cdot v ) / {d}^{2} \qquad ( Equation 5 )$$

It is understood from (Equation 5) that the pipe resistance P is in inverse proportion to the square of the diameter “d” of the thermal via. That is, the pipe resistance P becomes larger as the diameter “d” of the thermal via becomes smaller.

3. The quantity of heat held by the molten solder flowing into the thermal via becomes smaller and the temperature is thus more likely to decrease as the diameter of the thermal via becomes smaller.

While the molten solder flows into the thermal via, heat transfers to the second layer (GND layer) which has a high specific heat and to which the thermal via is connected, and thus the temperature gradually decreases. When it is assumed that molten solder that has flowed into the thermal via, which has a diameter of “d” and a unit height of ΔL, has a quantity of heat, the quantity of heat is simply in proportion to the volume of the solder. A quantity Q of heat is expressed by (Equation 6) below.

$$Q = {π ( d \cdot 2 )}^{2} \cdot Δ L \qquad ( Equation 6 )$$

Thus, the quantity Q of heat is in proportion to the square of the diameter “d” of the thermal via. That is, the quantity of heat held by the molten solder becomes smaller as the diameter of the thermal via becomes smaller. This quantity Q of heat is conducted to the copper foil 18 of the second layer (GND layer) while the molten solder flows into the thermal via. Accordingly, it is assumed that the temperature of the molten solder is gradually decreased.

The decrease in temperature of the molten solder affects the contact angle “θ” of the surface tension. For example, in a case where the solder is Sn-3Ag-0.5Cu and the temperature is 238° C., the surface tension T is 0.44 N/m and the contact angle “θ” is 65°. Surface tension tends to decrease as the temperature becomes higher. The change of the contact angle “θ” decreases as the temperature becomes higher. In a case where the temperature of the solder is 258° C., the contact angle “θ” is 59°. That is, the contact angle “θ” becomes larger as the temperature becomes lower. Thus, when the molten solder is cooled and its temperature is decreased while flowing through the thermal via, the contact angle “θ” is increased, and the vertical-direction component F of the surface tension is decreased.

Further, the decrease in temperature affects the viscosity “μ” of the molten solder regarding the pipe resistance P. The viscosity “μ” of the molten solder becomes the following values in a temperature range of from about 490 K to about 560 K in the case of, for example, solder of Sn-3Ag-0.5Cu.
At the time of 495 K (=220.85° C.), viscosity μ=1.65 mPa·s
At the time of 520 K (=246.85° C.), viscosity μ=1.62 mPa·s
At the time of 550 K (=276.85° C.), viscosity μ=1.5 mPa·s

That is, the solder has a higher viscosity as the temperature becomes lower. From (Equation 5) above, the pipe resistance P is in proportion to the viscosity “u”, and hence the pipe resistance P becomes larger as the solder temperature becomes lower. Thus, when the molten solder is cooled and its temperature is decreased while flowing through the thermal via, the solder viscosity “u” is increased, and the pipe resistance P is increased.

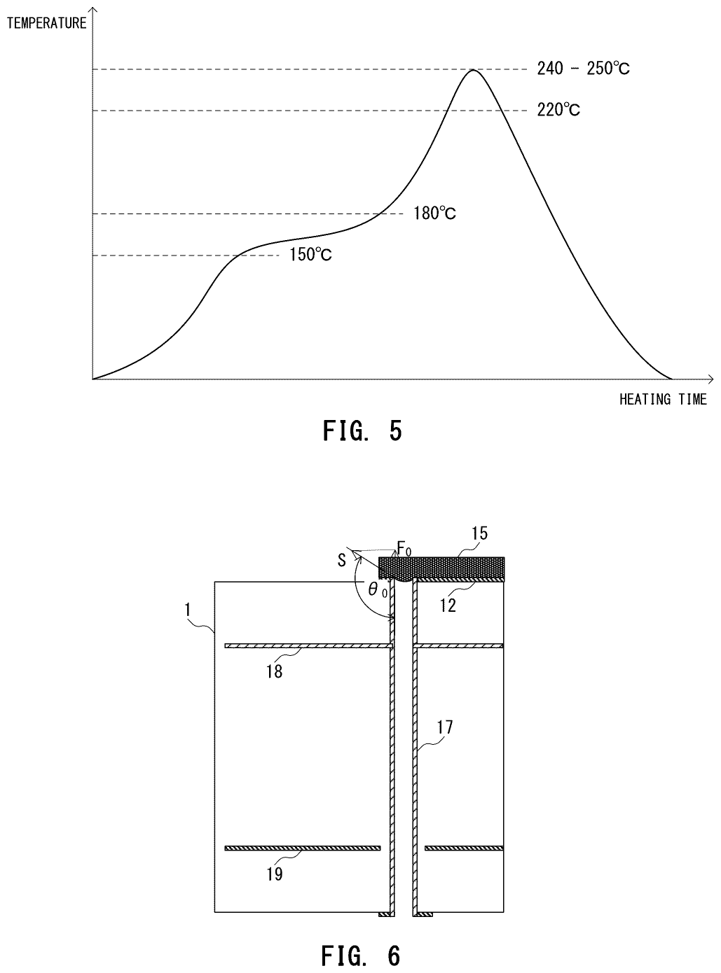

From the facts described above, it is inferred that, at the time of temperature rise caused by reflow, the solder paste near the thermal via flows into the thermal via in the following process. FIG. 6 to FIG. 8 are explanatory views of the process in which the solder paste flows into the thermal via 17.

(1) At normal temperature (25° C.), a lead-free solder paste (general solder paste of Sn-3.0Ag-0.5Cu) is applied to the heat transfer pattern 12.

(2) Reflow is started so that, in the pre-heat period (150° C. to 180° C.), flux in the solder paste (having a main component of abietic acid (C₁₉H₂₉COOH) and a melting point of 174° C.) melts.

(3) The molten flux flows into the thermal via 17 due to the capillary phenomenon and penetrates through the plated layer inside of the thermal via 17, to thereby decrease the contact angle θ inside of the thermal via. Further, part of the flux is vaporized and evaporated.

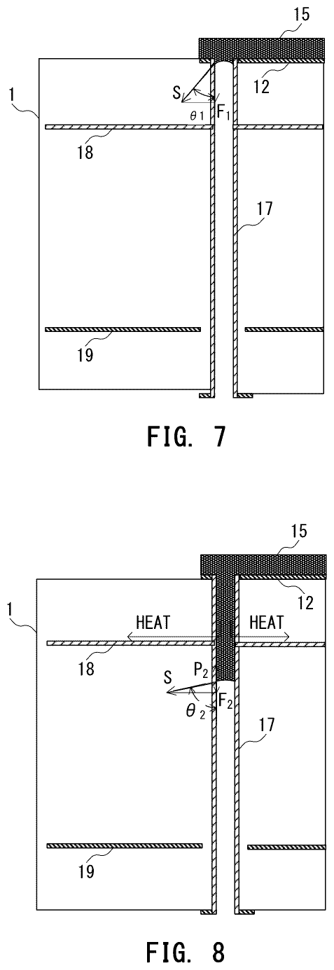

(4) In the main heating period (180° C. to 220° C.), on the reflow upper surface side, the solder exceeds a liquid phase temperature (219° C.) to melt. The molten solder does not flow into the thermal via 17 by a vertical-direction component F₀ of the surface tension at the time of a contact angle θ₂≥90° (FIG. 6). When the solder temperature rises due to heating to satisfy a contact angle θ₁<90°, the solder starts to flow into the thermal via 17 by a vertical-direction component F₁ of the surface tension due to the capillary phenomenon (FIG. 7).

(5) The molten solder that has flowed into the thermal via 17 has the quantity Q of heat, but the heat is conducted to the second layer (GND layer) connected to the thermal via 17 in the inner layer of the circuit board 1 so that the temperature is decreased. The decrease in temperature of the solder that has flowed into the thermal via 17 causes increase in contact angle θ (θ₁→θ₂) and decrease in surface tension (FIG. 8).

Further, in a case where the molten solder is regarded as a viscous fluid, the molten solder that has flowed into the pipe of the thermal via 17 has the pipe resistance P. The decrease in temperature of the molten solder causes increase in viscosity and also increase in pipe resistance. When the surface tension and the pipe resistance are balanced, the acceleration becomes zero (motion of uniform velocity), and the molten solder does not accelerate any more. When solder further flows into the thermal via 17 and its temperature is decreased, the surface tension becomes smaller than the pipe resistance. In this case, the acceleration becomes negative, and an inflow velocity decreases. The inflow stops when an inflow velocity “v” becomes zero. Further, when the temperature of the molten solder becomes a solid-phase temperature (217° C.) or less due to the temperature decrease, the molten solder is solidified to have no flowability.

In Item (5) above, when the inflow velocity “v” is positive even at the lowermost portion of the thermal via 17, the molten solder protrudes from the lower portion of the thermal via 17. Meanwhile, in Item (5), when the inflow velocity “v” becomes 0 before the molten solder reaches the lowermost portion inside of the thermal via 17, the solder does not protrude from the lower portion of the thermal via 17.

As described above, a condition for preventing the solder from protruding from the thermal via 17 resides in that the inflow velocity “v” of the molten solder becomes 0 before the molten solder reaches the lowermost portion inside of the thermal via 17. The condition for preventing the solder from protruding as described above has been found by setting the diameter of the thermal via to be equal to or smaller than 0.25 mm, which is a diameter smaller than normal, without changing the reflow temperature profile from the related-art profile.

### <When Second IC Package 3 is Mounted on Primary Surface, and First IC Package 2 is Yet to be Mounted>

The second IC package 3 is mounted on the primary surface (second surface 200) in the first reflow step (see FIG. 4). In a case where the solder protrudes to the secondary surface from the thermal via 17 in the first reflow step, a squeegee may be caught in a step of applying a solder paste to the secondary surface, and thus there is a possibility that the quality of the surface on which the solder paste is applied is reduced. However, in the first embodiment, the diameter of the thermal via 17 is set to be equal to or smaller than 0.25 mm, which is a diameter smaller than normal, and hence the protrusion of the solder to the secondary surface is suppressed. Accordingly, no reduction in quality of the surface on which the solder paste is applied is caused, and hence reduction in yield of the circuit board due to the solder flowing into the thermal via 17 can be suppressed.

### Second Embodiment

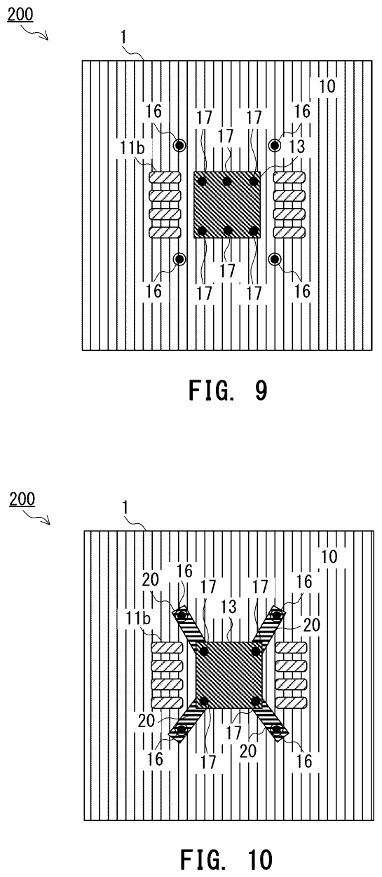

In the first embodiment, a description has been given of an example in which the diameter of the thermal via 17 on the inner side of the heat transfer pattern 13 for the second IC package 3 is set to be smaller than that of a normal through via. However, reduction in diameter of the thermal via 17 also causes reduction in efficiency of heat dissipation. Accordingly, in a second embodiment of the present disclosure, the number of thermal vias 17 formed in the heat transfer pattern 13 is increased. FIG. 9 is an exemplary view of a wiring pattern on the second surface side in a case in which the number of thermal vias 17 each having a diameter smaller than normal is increased by two as compared to the case of FIG. 3, along two sides of the heat transfer pattern 13. With the number of the thermal vias 17 being increased, the heat dissipation efficiency that has been reduced because of the decrease in diameter can be increased.

### Third Embodiment

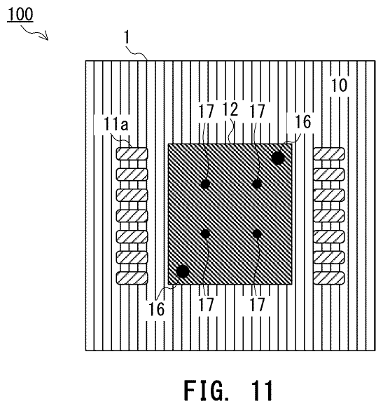

In a third embodiment of the present disclosure, the second IC package 3 also uses the thermal vias 16 which are formed in a normal size, for heat dissipation. FIG. 10 is an exemplary view of a wiring pattern on the second surface side in a case in which the thermal vias 16 and the heat transfer pattern 13 are connected to each other. The thermal vias 16 and the heat transfer pattern 13 are connected to each other by heat dissipation paths 20. The thermal vias 16 are separated away from the heat transfer pattern 13, and hence the heat dissipation performance itself is reduced, but the thermal vias 16 can be used for heat dissipation of heat conducted through the heat dissipation paths 20.

In a case where the heat dissipation paths 20 are simply provided, there is a possibility that the molten solder flows into the thermal via 16 via the heat dissipation path 20 so that the solder protrudes to the secondary surface side. Accordingly, the heat dissipation paths 20 may be covered with the solder resist 10. It is preferred that the solder resist 10 cover a part of the second surface 200 other than the heat transfer pattern 13 and the land 11b for lead connection.

### Fourth Embodiment

In each of the first to third embodiments, the number of thermal vias 16 is four. In a case where the thermal vias 17 are formed on the inner side of the heat transfer pattern 12, the heat dissipation amount may become large relative to the heat generation amount in a case where the number of thermal vias 16 is four because the thermal vias 17 also exhibit heat dissipation. Accordingly, the number of thermal vias 16 may be reduced to achieve a heat dissipation amount corresponding to the heat generation amount. FIG. 11 is an exemplary view of a wiring pattern on the second surface side in a case in which the number of thermal vias 16 is reduced. In FIG. 11, the number of thermal vias 16 is reduced by two, and there are two thermal vias 16 at two corners of the heat transfer pattern 12.

As described above, the first to fourth embodiments have a feature in the through vias (thermal vias 16 and 17) formed in the heat transfer patterns 12 and 13 to which the electronic parts (first IC package 2 and second IC package 3) are caused to adhere. Specifically, the two electronic parts to be exclusively mounted on the front and back surfaces of the circuit board 1 have different sizes. The size of the through via (thermal via 17) formed in the mounting region (heat transfer pattern 13) for the electronic part having a smaller size is set to be smaller than the size of the through via (thermal via 16) formed outside of this mounting region (heat transfer pattern 13).

With such a configuration, the molten solder is prevented from flowing into the through via to reach the opposite surface at the time when the electronic part is mounted. Accordingly, a sufficient amount of solder for mounting the electronic part can be ensured, and the electronic part can be mounted with a sufficient strength. In this manner, the yield of the circuit board 1 can be prevented from being reduced.

The circuit board 1 described in each of the above-mentioned embodiments is mounted on, for example, an image forming apparatus. The image forming apparatus includes a constituent part to be controlled by any one of the first IC package 2 and the second IC package 3 mounted on the circuit board 1 to form an image on a predetermined sheet.

In each of the above-mentioned embodiments, a description has been given of an example in which the first IC package 2 and the second IC package 3 are replacement parts. However, the effect to be obtained by the third embodiment is not limited to such an example. For example, in some cases, the circuit board 1 is designed as a common platform with respect to a plurality of apparatus. At this time, in one model, the first electronic part having a first function is mounted on the first surface, while, in another model, the second electronic part different from the first electronic part is mounted on the second surface. In such a case as well, the effect described in the embodiments can be obtained.

In a case where a plurality of through vias for heat dissipation are formed in the circuit board, there is a possibility that a large amount of solder flows into the through via depending on the position of the through via. This state leads to reduction of an amount of solder required for mounting the IC package, and causes the IC package to be mounted to the circuit board at an insufficient strength. In a case where the IC package is mounted to the circuit board at an insufficient strength, the yield of the circuit board is reduced, and thus the yield of the apparatus on which this circuit board is mounted is reduced. According to the present disclosure, the circuit board with which the reduction of the yield due to solder inflow can be suppressed while the solder inflow into the through via is suppressed can be provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-126986, filed Aug. 3, 2023, which is hereby incorporated by reference herein in its entirety.

What is claimed is:

1. A circuit board comprising:
a first surface having a first mounting region configured so that a first electronic part is mounted or mountable to the first mounting region; and
a second surface having a second mounting region configured so that a second electronic part is mounted or mountable to the second mounting region, the second surface being different from the first surface; and
a plurality of through vias penetrating through the circuit board, including at least a first through via and a second through via,
wherein the circuit board includes an overlapping region in which the first mounting region and the second mounting region overlap each other as viewed from a direction perpendicular to the first surface, and
wherein the first through via is arranged in the overlapping region, and
the second through via has an opening area different from an opening area of the first through via.

2. The circuit board according to claim 1, further comprising:
a first heat transfer pattern to which the first electronic part is adherable; and
a second heat transfer pattern to which the second electronic part is adherable,
wherein the first through via connects the first heat transfer pattern and the second heat transfer pattern to each other.

3. The circuit board according to claim 2, wherein the first heat transfer pattern has a size larger than a size of the second heat transfer pattern.

4. The circuit board according to claim 2, wherein the first through via is formed in a region in which the first heat transfer pattern and the second heat transfer pattern overlap each other as viewed from the direction.

5. The circuit board according to claim 1, wherein the second through via is formed in a region in which the first mounting region and the second mounting region do not overlap each other as viewed from the direction.

6. The circuit board according to claim 2, further comprising a heat dissipation path connecting the second through via and the second heat transfer pattern to each other, the heat dissipation path being covered with a solder resist.

7. The circuit board according to claim 5, wherein the number of the first through vias is larger than the number of the second through vias.

8. The circuit board according to claim 2,
wherein the first heat transfer pattern and the second heat transfer pattern each have a rectangular shape,
wherein the first through via is formed at each of four corners of the second heat transfer pattern, and
wherein the second through via is formed at each of four corners of the first heat transfer pattern.

9. The circuit board according to claim 2,
wherein each of the first heat transfer pattern and the second heat transfer pattern has a rectangular shape,
wherein the first through via is formed at each of four corners of the second heat transfer pattern and positions along two sides of the second heat transfer pattern, and
wherein the second through via is formed at each of four corners of the first heat transfer pattern.

10. The circuit board according to claim 2,
wherein the first heat transfer pattern and the second heat transfer pattern each have a rectangular shape,
wherein the first through via is formed at each of four corners of the second heat transfer pattern, and
wherein the second through via is formed at each of two corners of the first heat transfer pattern.

11. The circuit board according to claim 1,
wherein the circuit board has a multilayer structure,
wherein the first through via and the second through via are configured to dissipate heat of the first electronic part to another layer, and
wherein the first through via is configured to dissipate heat of the second electronic part to another layer.

12. The circuit board according to claim 2,
wherein the first electronic part and the second electronic part each include a heat dissipation plate,
wherein the heat dissipation plate of the first electronic part is adherable to the first heat transfer pattern, and
wherein the heat dissipation plate of the second electronic part is adherable to the second heat transfer pattern.

13. The circuit board according to claim 1,
wherein the first through via has a diameter of 0.25 mm or less, and
wherein the second through via has a diameter of 0.3 mm.

14. An image forming apparatus comprising:
the circuit board according to claim 1; and
a constituent part to be controlled by either one of the first electronic part or the second electronic part to form an image.
